(19) United States
(12) Patent Application Publication
(10) Pub. No.: US 2016/0128208 A1
(43) Pub. Date: May 5, 2016

(54) ELECTRICAL CONTROL DEVICE

(71) Applicant: WABCO GmbH, Hannover (DE)

(72) Inventors: Thomas Bolik, Hannover (DE); Tobias Kortlang, Gehrden (DE)

(21) Appl. No.: 14/897,519

(22) PCT Filed: May 24, 2014
(86) PCT No.: PCT/EP2014/001406

§ 371 Date: Dec. 10, 2015

(30) Foreign Application Priority Data
Jun. 28, 2013 (DE) 10 2013 010 843.8

(51) Int. Cl. H05K 5/00; H05K 7/20

(52) U.S. Cl. CPC H05K 5/0052; H05K 5/0008; H05K 5/0013; H05K 7/205

(57) ABSTRACT

An electrical control device (10, 70, 90) including a housing (12) for accommodating a printed circuit board (14), on which an electronic circuit (18) is arranged, wherein the printed circuit board (14) rests at least partially on a metallic heat sink (24) which forms a lower housing part (20), and is covered completely by an upper housing part (22), and in which electrical control device (10, 70, 90) the two housing parts (20, 22) are joined by a frictionally locking connection and are sealed with respect to one another by a circumferential sealing element (44). As a result, the housing (12) has a simple structural and vibration-resistant design which permits cost-effective large-scale fabrication.

### TECHNICAL FIELD

The invention relates to an electrical control device comprising a housing for accommodating a printed circuit board, on which an electronic circuit is arranged, wherein the printed circuit board rests at least partially on a metallic heat sink which forms a lower housing part, and is covered completely by an upper housing part, and in which electrical control device the two housing parts are joined by a frictionally locking connection and are sealed with respect to one another by a circumferential sealing element.

### BACKGROUND OF THE INVENTION

Electrical control devices having a housing for hermetically encapsulating electronic components are widely used in the technical field in order, in particular, to protect as well as possible the sensitive electronic components and conductor tracks against damaging environmental influences such as, for example, strong vibrations, high or low ambient temperatures, moisture, chemically aggressive substances, electromagnetic interference fields and the like. These requirements are of particular significance, especially given the large increase in the use of electronic components or entire electronic assemblies in mobile applications such as, for example, in vehicles of all types. Furthermore, in order to reduce the thermal loading of the electronic components used in an electrical control device it is known to bond a printed circuit board to a heat sink.

DE 10 2007 029 913 A1 discloses an electrical control device in which a conductor track substrate is equipped on both sides with electronic and/or electrical components. The electrical components on each side of the conductor track substrate are each covered with a trough-shaped housing part, wherein there is an intermediate space between the electrical components and the respective housing part. Furthermore, there is in each case a sealing ring between the first and second housing parts and the conductor track substrate. Outside the electrical components which are covered by the housing parts and outside a zone of the conductor track substrate which is provided with a device plug, a contact point is provided for connecting a further external electrical component. Furthermore, a housing part is mounted directly on a heat sink for the optimized conduction away from the waste heat which is output by the electrical components. In an alternative embodiment to this, merely one side of the conductor track substrate, pointing away from the heat sink, is covered with a housing part, whereas the second side of the conductor track substrate facing away therefrom rests at least partially directly on the heat sink, which for this purpose has a recess as a means of compensating the heights of the components on the second side. Furthermore, in this configuration an intermediate layer which is formed with a heat-conducting layer is located between the conductor track substrate and the heat sink. A disadvantage of this electrical control device is the large amount of structural expenditure, which entails comparatively high fabrication costs.

DE 10 2006 000 958 A1 describes an electrical device, in particular a power distributor for a motor vehicle. The power distributor has, inter alia, two circuit carriers and at least one contact element for the feeding-in current, wherein the contact element is connected to a busbar, which is held by at least one sprung connecting element. The connection of the two circuit carriers to one another and the electrical connection of the circuit carriers to external electrical connections is carried out by means of press-in technology which is known per se. For this purpose, on the one hand, press-in pins and, on the other hand, blade contacts are provided as connecting elements which interact in order to form a contact. However, the power distributor likewise does not have a hermetically encapsulated housing or a means of cooling electrical and/or electronic components with a high level of waste heat.

EP 0 902 609 A1 discloses a method for manufacturing a printed circuit board, provided with a bonded-on cooling plate, as a composite component, a composite component which is manufactured with such a method and an arrangement for carrying out the method. The printed circuit board has, as does the bonded-on cooling plate, a preferably rectangular shape, wherein the shape of the cooling plate does not necessarily follow that of the printed circuit board. An adhesive film which is provided on both sides with protective foils, can be transferred in a dry state and is permanently elastic, such as, for example as is marketed by the company 3M® under the brand name “Isotac®” is used as the bonding agent. The method in said document or a rocker-like arrangement which is used to carry out the same permit largely air-bubble-free execution of the bonding by means of a special bonding technique as well as by means of thermal post-treatment. Mechanical stresses owing to different thermal length-compensation coefficients of the cooling plate and printed circuit board, which stresses can cause fracturing of the printed circuit board and of the solder points, are avoided by means of the adhesive film. A disadvantage of this known technology is the fact that the conductor track substrate is preferably not equipped until after the printed circuit board and cooling plate have been bonded over their entire surface, in order to limit the mechanical and/or thermal stressing of the electronic components.

### SUMMARY

The invention is therefore based on the object of proposing an electrical control device having a housing for accommodating a printed circuit board which bears an electronic circuit, which control device is easy and cost-effective to manufacture and also largely vibration-resistant.

The invention is based on the realization that the manufacturing outlay on an electrical control device can generally be reduced, and as a result the associated unit costs can be lowered if individual housing components of the electrical control device perform a double function.

The invention therefore relates to an electrical control device comprising a housing for accommodating a printed circuit board, on which an electronic circuit is arranged, wherein the printed circuit board rests at least partially on a metallic heat sink which forms a lower housing part, and is covered completely by an upper housing part, and in which electrical control device the two housing parts are joined by a frictionally locking connection and are sealed with respect to one another by a circumferential sealing element. In order to achieve the stated object, there is provision that the upper housing part is formed with a plastic material, and that the upper housing part has a plug-type connection which is formed integrally thereon and has at least two press-in contacts for electrically connecting the printed circuit board to an external electrical circuit.

As a result, a control device having a housing with an integrated heat sink for accommodating a printed circuit board with a multiplicity of electronic and/or electrical components arranged thereon is provided which is easy to manufacture and has a high level of vibration resistance. Furthermore, the structural design of the control device makes low requirements in terms of the dimensional accuracy of the individual components used and permits unproblematic compensation of any component tolerances, with the result that the electrical control device can be manufactured comparatively easily and cost-effectively. In order to optimize the mechanical loadability of the electrical control device further, the electrically insulating plastic material of the housing is preferably provided with fiber reinforcement composed of fibers which are also electrically non-conductive, such as, for example glass fibers or the like.

In one advantageous refinement there is provision that the control device is embodied in such a way that as a result of the joining of the two housing parts, the electrical formation of contact of the printed circuit board occurs automatically by the at least two press-in contacts. As a result, particularly simple, rapid and cost-effective integration of the printed circuit board into the housing and the formation of contact thereof is possible. The satisfactory functioning of the electrical formation of contact after joining can easily be detected, for example using an electrical conductivity test.

In a further advantageous development there is provision that an intermediate layer for improving the transfer of heat is arranged at least partially between an underside of the printed circuit board and the lower housing part. As a result, the cooling of the electronic components which are arranged on the printed circuit board is optimized further, since any surface irregularities of the lower housing part and of the printed circuit board are compensated by the intermediate layer. This intermediate layer which is preferably an extremely good conductor of heat may be quite generally an adhesive layer, a thermally conductive adhesive, a permanently elastic thermally conductive paste, an acrylic film, an acrylic adhesive, what is referred to as a gap pad or what is referred to as a gap filler.

Furthermore, there may preferably be provision that a projection, which projects into the interior space of the housing, is formed at least in certain sections in the region of a circumferential housing edge which is formed on the upper housing part, which projection rests after the joining of the two housing parts against the side of the printed circuit board facing the upper housing part. As a result, after the joining of the two housing parts the printed circuit board is automatically clamped in between the latter mechanically and secured in position.

In one favorable refinement, the lower housing part has in each case a cutout in the region of the at least two press-in contacts. As a result, a short-circuit via the electrical-current-conducting press-in contacts with the lower housing part which is formed from a metallic material and acts as a heat sink can be avoided.

According to a further advantageous refinement, the housing edge of the upper housing part has a circumferential groove with an approximately V-shaped cross-sectional geometry. As a result, during mounting the orientation of the upper housing part is favored with respect to the lower housing part. The precise orientation of the two housing parts with respect to one another is achieved by guide elements (not illustrated) on a joining tool and/or on the two housing parts. Furthermore, the connecting rigidity of the upper housing part is optimized by the circumferential groove.

The lower housing part has at the edge a circumferential projection, which interacts with the circumferential groove in the upper housing part, with an approximately V-shaped cross-sectional geometry which extends in the direction of the groove in the upper housing part. This facilitates the connection of the upper housing part to the lower housing part and the arrangement of a sealing means or sealing element between the two.

According to a further refinement, the sealing means or sealing element is therefore arranged between the groove of the upper housing part and the projection of the lower housing part. As a result, the sealing effect between the two housing parts is improved further, since, in particular, slipping of the preferably rod-shaped or annular sealing element after the joining of the two housing parts is avoided.

According to another development of the subject matter of the invention it is possible to provide that the lower housing part has a trough-shaped recess of low depth for accommodating the printed circuit board and securing it positionally with respect to forces acting perpendicularly with respect to its surface normal, wherein the depth of this recess corresponds at maximum to the thickness of the printed circuit board. As a result, the printed circuit board is already locked directly in the lower housing part, preventing shifting of said printed circuit board.

The sealing element is preferably formed with or from an elastic plastic material, in particular with or from an elastomer, with an approximately V-shaped cross-sectional geometry. As a result, a reliable sealing effect of the housing is provided even under difficult conditions of use or ambient conditions of the control device.

According to another advantageous refinement, the press-in contacts are embodied in a pin shape and each have an end tip which can be pressed into the printed circuit board. As a result, standard plug-type sleeves, which are in widespread use in electrical circuit technology, can be plugged, as part of a plug, onto the pin-shaped press-in contacts of the plug trough of the housing. The press-in contacts have here end tips which point in the direction of the printed circuit board and can be pressed into the printed circuit board with relatively little application of force, in order to provide an electrically conductive connection between the conductor tracks of the printed circuit board and the press-in contacts. The electrical connection between the electrical control device, which can be, for example, a control device for an anti-lock brake system of a motor vehicle and an external electrical circuit can then be established by plugging using sleeves or contact springs which can be plugged onto the press-in contacts.

Furthermore, it can be provided that the frictionally locking connection of the upper housing part to the lower housing part is realized by means of at least one snap-in element which is formed integrally on the housing edge of the upper housing part and which can be latched to the lower housing part. As a result, the electrical control device can be mounted particularly quickly and, if necessary, opened again quickly, without a tool.

In an alternative embodiment to this, there is provision that the frictionally locking connection of the upper housing part to the lower housing part is formed by at least one attachment element, such as a screw and/or a rivet. As a result, a connection is provided between the two housing parts of the electrical device which can be particularly loaded mechanically.

In a third connection variant there is provision that the printed circuit board is connected to the lower housing part by at least one attachment element such as a screw and/or a rivet. As a result, the printed circuit board is secured in position within the housing particularly reliably with respect to forces acting from the outside.

Further aspects of the invention are explained in greater detail below by means of preferred illustrative embodiments with reference to the attached drawings. The drawings are provided for purely illustrative purposes and are not intended to limit the scope of the present invention.

### BRIEF DESCRIPTION OF THE DRAWINGS

For the sake of better understanding of the invention, a drawing with three exemplary embodiments is appended to the description, in which:

FIG. 1 shows a cross-sectional illustration of a first embodiment of an electrical control device embodied according to the invention,

FIG. 2 shows a cross-sectional illustration of a second embodiment of the electrical control device, and

FIG. 3 shows a cross-sectional illustration of a third embodiment of the electrical control device.

### DETAILED DESCRIPTION OF THE DRAWINGS

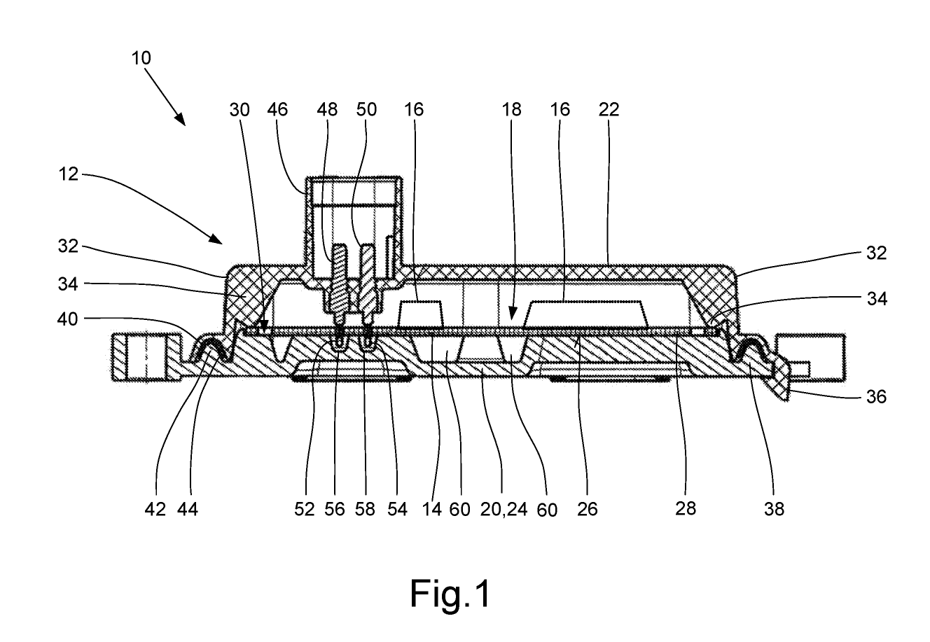

In the drawing, the same structural elements each have the same reference number. FIG. 1 accordingly has a schematic cross-sectional illustration of a first embodiment of an electrical control device 10 according to the invention. This control device 10 has a housing 12 in which a printed circuit board 14 is accommodated, which printed circuit board 14 has a plurality of electronic and/or electrical components 16 which are connected to one another by conductor tracks and vias and which together form an electronic circuit 18.

The housing 12 is constructed from an essentially planar or plate-shaped lower housing part 20 and an upper, trough-shaped housing part 22. The lower housing part 20 serves, in addition to its primary housing function, at the same time as a heat sink 24 for conducting away the waste heat which is released at the electronic and/or electrical components 16. The upper housing part 22 is preferably formed from an, if appropriate, fiber-reinforced plastic material, while the lower housing part 20 is composed of a metallic material which is as good a thermal conductor as is possible, for example aluminum, copper and/or some other metal alloy.

In order to facilitate the transfer of heat between the printed circuit board 14 and the lower housing part 20 which serves as a heat sink 24, a planar intermediate layer 28 which has a low thermal resistance is arranged, at least partially, between an underside 26 of the printed circuit board 14 and the lower housing part 20. This intermediate layer 28 can be an adhesive layer, a thermally conductive adhesive, a permanently elastic thermally conductive paste, an acrylic film, an acrylic adhesive, what is referred to as a gap pad or what is referred to as a gap filler.

The printed circuit board 14 is accommodated in a flat, trough-shaped recess 30 in the lower housing part 20 in such a way that the printed circuit board 14 is secured in the position shown at least with respect to mechanical forces which act on the two housing parts 20, 22, perpendicularly with respect to the surface normal of the printed circuit board 14. The external circumferential contour of the recess 30 essentially follows the external circumferential contour of the printed circuit board 14 here.

In the region of a circumferential housing edge 32 of the upper housing part 22, a projection 34 with an approximately V-shaped cross-sectional geometry is formed on the inside. In the closed state of the housing 12 according to FIG. 1, the projection 34 presses onto the upper side of the printed circuit board 14 accommodated in the recess 30, with the result that said printed circuit board 14 is clamped in a mechanically secure fashion at the edge between the lower housing part 20 and the projection 34 in the upper housing part 22, and is secured on all sides in the position shown in conjunction with the recess 30 in the lower housing part 20. The frictionally locking connection between the two housing parts 20, 22 is realized structurally in the embodiment of the control device 10 according to FIG. 1 by at least one snap-in hook 36 which is formed on the housing edge 32 of the upper housing part 22, integrally thereon, and in the state shown in FIG. 1 engages at least in certain sections around a housing edge 38 of the lower housing part 20 in a positively locking fashion. As a result of the fact that the upper housing part 22 can be latched to the lower housing part 20 by the snap-in hook 36, the electrical control device 10 can be mounted and, if appropriate, removed again, easily, quickly and in an optimum way in terms of costs.

In the region of the housing edge 32 of the upper housing part 22, there is also a groove 40 with an approximately V-shaped cross-sectional geometry. A circumferential projection 42 with an approximately V-shaped cross-sectional geometry, which is configured so as to correspond to the groove 40, is arranged on the lower housing part 20, wherein the projection 42 is directed in the direction of the groove 40. In order to ensure a hermetic seal of the housing 12 with respect to the surroundings, a circumferential rod-shaped sealing element 44 is inserted with a likewise approximately V-shaped cross-sectional geometry into the groove 40. The sealing element 44 is preferably formed from an elastic plastic material, in particular with an elastomer or the like. As a result of the fact that the projection 42 engages in the groove 40 with the sealing element 44 which is inserted therein, precise and automatic orientation of the two housing parts 20, 22 with respect to one another in the horizontal direction is ensured at the same time.

In order to connect the control device 10 electrically to an external electrical circuit (not illustrated), a plug-type connection 46 which is preferably embodied in the manner of a plug trough with two pin-shaped press-in contacts 48, 50 is integrally formed on the upper housing part 22 using the same material. Two end tips 52, 54 of the press-in contacts 48, 50 are pressed into the printed circuit board 14 in the closed state of the housing 12 which is shown here, and they therefore establish the desired electrically conductive connection between the electronic circuit 18 and an external circuit (not illustrated in the drawings). The formation of contact or the electrical connection with the external circuit occurs here automatically when the upper housing part 22 is latched onto the lower housing part 20.

In order to avoid short-circuits in the region of the end tips 52, 54 of the press-in contacts 48, 50 through the electrically conductive heat sink 24 in the form of the lower housing part 20, in each case a small cutout 56, 58 is let into the electrically conductive lower housing part 20 or heat sink 24 underneath the end tips 52, 54. The end tips 52, 54 therefore do not touch the lower housing part 20 even though they penetrate the printed circuit board 14 in the exemplary embodiments in FIGS. 1 to 3.

Furthermore, cavities 60 can optionally be present underneath the printed circuit board 14 in the lower housing part 20, so that the printed circuit board 14 does not rest with its entire surface on the lower housing part 20, serving as a heat sink 24, with the intermediate layer 28. The cavities 60 can, if necessary, be positioned underneath electronic components 16 which output comparatively little waste heat, or, in the case of double-sided equipping of the printed circuit board 14, can accommodate electronic components.

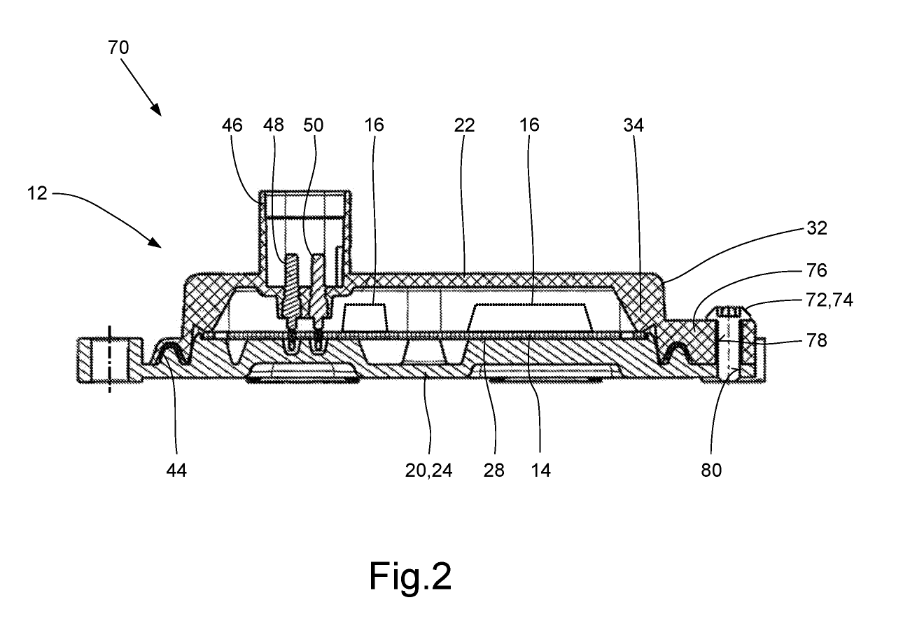

FIG. 2 shows a second embodiment of an electrical control device 70 which is embodied according to the invention. The housing 12 of this control device 70 is constructed in turn with the upper housing part 22 and the lower housing part 20, wherein the lower housing part 20 acts at the same time as a heat sink 24. A printed circuit board 14 including the intermediate layer 28 is also clamped in between the two housing parts 20, 22, wherein the printed circuit board 14 is connected in an electrically conductive fashion to the external circuit via the two press-in contacts 48, 50 of the plug-type connection 46. The seal between the two housing parts 20, 22 is also provided in this exemplary embodiment by the rod-shaped sealing element 44 which has already been described. In the closed state of the housing 12 shown in FIG. 2, the printed circuit board 14 is clamped in a mechanically secure fashion between the two housing parts 20, 22 by the circumferential projection 34 or bead which is formed on the inside in the region of the housing edge 32.

In contrast to the first embodiment of the control device 10 according to FIG. 1, in the control device 70 according to FIG. 2 at least one separate attachment element 72, which is implemented here, by way of example, as a screw 74, is provided instead of the snap-in hook 36 in the region of the housing edge 32 of the upper housing part 22. Instead of the screw 74, a rivet, an expanding dowel or the like can also be used.

In order to accommodate the screw 74, a horizontal flange 76 with a continuous drilled hole 78 is formed integrally on the housing edge 32 of the upper housing part 22. The drilled hole 78 runs parallel to the surface normal of the printed circuit board 14. The flange 76 has an approximately rectangular cross-sectional geometry. A threaded drilled hole 80 is formed in the lower housing part 20 flush with the drilled hole 78. The screw 74 is guided through the drilled hole 78 in the flange 76 of the upper housing part 22 and screwed into the threaded drilled hole 80 of the lower housing part 20 to form the desired frictionally locking mechanical connection, which can, if appropriate, be easily released again, between the two housing parts 20, 22. Instead of the threaded drilled hole 80 in the lower housing part 20, it is alternatively also possible to screw on the underside a self-locking nut or the like onto the screw 74. Furthermore, it is possible to press a nut or a threaded bush into the lower housing part 20 instead of the threaded drilled hole 80. As a result, a mechanically highly loadable and vibration-resistant screw connection is provided between the two housing parts 20, 22.

In contrast to the one attachment element 72 which is illustrated merely by way of example, a multiplicity of attachment elements can preferably be arranged spaced uniformly apart from one another in the region of the flange 76. Furthermore, it is possible to combine the latched connection or snap-in hook connection between the two housing parts 20, 22 according to FIG. 1 with the screw connection (shown in FIG. 2) of the two housing parts 20, 22. This results, inter alia, in the advantage that in the course of the fabrication of the control device the two housing parts 20, 22 are quickly latched to one another and initially reliably secured in their position with respect to one another, with the result that further fabrication steps, including the ultimate mechanical stressing of the two housing parts 20, 22 using the attachment elements 72 can occur independently of the connection process of the housing parts 20, 22.

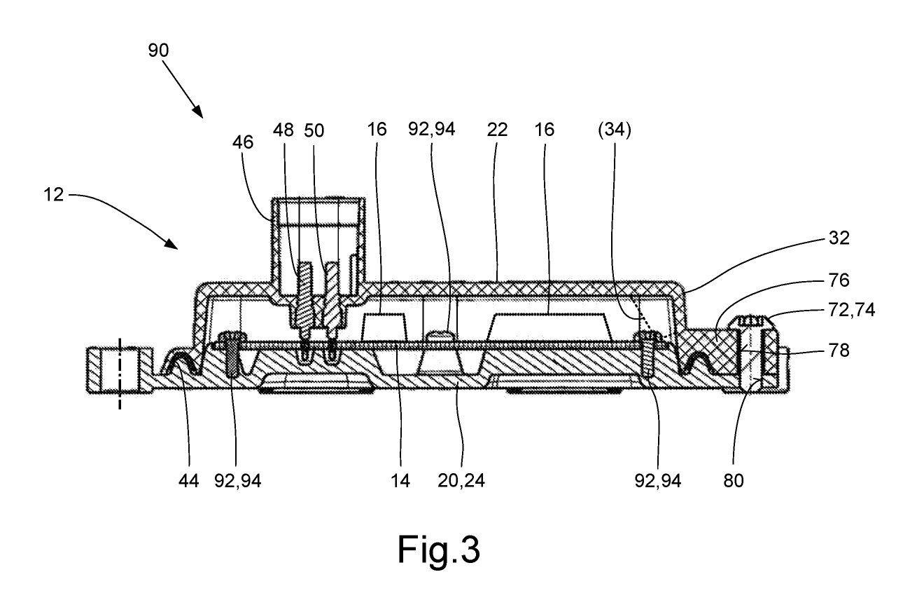

FIG. 3 shows a third embodiment of the electrical control device 90 according to the invention. The housing 12 of this control device 90 is also constructed from two housing parts 20, 22, wherein the lower housing part 20 serves at the same time as a heat sink 24. A printed circuit board 14, into which the two press-in contacts 48, 50 of the plugtype connection 46 are pressed, is clamped in between the two housing parts 20, 22. Owing to the circumferential sealing element 44 which is clamped in securely between the two housing parts 20, 22, a hermetically sealed encapsulation of the printed circuit board 14 is ensured. The two housing parts 20, 22 are in turn joined by a screw connection according to the second embodiment in FIG. 2, wherein the screw 74 is guided as an attachment element 72 through the drilled hole 78 of the flange 76 of the upper housing part 22 and screwed to the threaded drilled hole 80 in the lower housing part 20. In contrast to the second embodiment according to FIG. 2, in the case of the electrical control device 90 according to FIG. 3 the printed circuit board 14 is additionally connected in a mechanically secure fashion to the lower housing part 20 with three attachment elements 92, wherein these attachment elements 92 are embodied by way of example as screws 94. Instead of the screws 94 which are shown, rivets, expansion dowels or other attachment elements can also be used.

Since the printed circuit board 14 is securely screwed to the lower housing part 20 by the three screws 94, the circumferential V-shaped projection 34, which, in the two first embodiments of the control device 90, is formed on the inside in the region of the housing edge 32 of the upper housing part 22, indicated here only with a dot-dash line and has the purpose of clamping in the printed circuit board 14 between the two housing parts 20, 22, can be dispensed with in the third embodiment of the control device 90.

While the above description constitutes the preferred embodiments of the present invention, it will be appreciated that the invention is susceptible to modification, variation and change without departing from the proper scope and fair meaning of the accompanying claims.

What is claimed is:

1. An electrical control device (10, 70, 90) comprising
a housing (12) for accommodating a printed circuit board (14), on which an electronic circuit (18) is arranged,
wherein the printed circuit board (14) rests at least partially on a metallic heat sink (24) which forms a lower housing part (20), and is covered completely by an upper housing part (22), and
wherein the two housing parts (20, 22) are joined by a frictionally locking connection and are sealed with respect to one another by a circumferential sealing element (44), wherein the upper housing part (22) is formed with a plastic material, and in that the upper housing part (22) has a plug-type connection (46) which is formed integrally thereon and has at least two press-in contacts (48, 50) for electrically connecting the printed circuit board (14) to an external electrical circuit.

2. The electrical control device (10, 70, 90) as claimed in patent claim 1, wherein said electrical control device (10, 70, 90) is embodied in such a way that as a result of the joining of the two housing parts (20, 22), the electrical formation of contact of the printed circuit board (14) occurs automatically by the at least two press-in contacts (48, 50).

3. The electrical control device (10, 70, 90) as claimed in claim 1, wherein an intermediate layer (28) for improving the transfer of heat is arranged at least partially between an underside (26) of the printed circuit board (14) and the lower housing part (20).

4. The electrical control device (10, 70, 90) as claimed in claim 1, wherein a projection (34), which projects into an interior space of the housing (12), is formed at least in certain sections near a circumferential housing edge (32) which is formed on the upper housing part (22), and wherein the projection (34) rests after the joining of the two housing parts (20, 22) against a side of the printed circuit board (14) facing the upper housing part (22).

5. The electrical control device (10, 70, 90) as claimed in claim 1, wherein the lower housing part (20) has a cutout (56, 58) near the at least two press-in contacts (48, 50).

6. The electrical control device (10, 70, 90) as claimed in claim 1, wherein the housing edge (32) of the upper housing part (22) has a circumferential groove (40) with an approximately V-shaped cross-sectional geometry.

7. The electrical control device (10, 70, 90) as claimed in claim 6, wherein the lower housing part (20) has at the housing edge (32) a circumferential projection (42) with an approximately V-shaped cross-sectional geometry which extends in the direction of the groove (40).

8. The electrical control device (10, 70, 90) as claimed in claim 1, wherein the lower housing part (20) has a trough-shaped recess (30) of low depth for accommodating the printed circuit board (14) and securing it positionally with respect to forces acting perpendicularly with respect to its surface normal, and wherein the depth of this recess (30) corresponds at maximum to a thickness of the printed circuit board (14).

9. The electrical control device (10, 70, 90) as claimed in claim 7, wherein the sealing element (44) is arranged between the groove (40) of the upper housing part (22) and the projection (42) of the lower housing part (20).

10. The electrical control device (10, 70, 90) as claimed in claim 1, wherein the sealing element (44) is formed with an elastic plastic material with an approximately V-shaped cross-sectional geometry.

11. The electrical control device (10, 70, 90) as claimed in claim 1, wherein the press-in contacts (48, 50) are embodied in a pin shape and each have an end tip (52, 54) which can be pressed into the printed circuit board (14).

12. The electrical control device (10) as claimed in claim 1, wherein the frictionally locking connection is formed by at least one snap-in element (36) which is formed integrally on the housing edge (32) of the upper housing part (22) and which can be latched to the lower housing part (20).

13. The electrical control device (70) as claimed in claim 1, wherein the frictionally locking connection is formed by at least one attachment element (72), such as a screw (74) or a rivet.

14. The electrical control device (90) as claimed in claim 1, wherein the printed circuit board (14) is connected to the lower housing part (20) by at least one attachment element (92) such as a screw (94) or a rivet.
